(19) United States
(12) Patent Application Publication
(10) Pub. No.: US 2010/0258154 A1
(43) Pub. Date: Oct. 14, 2010

(54) THERMOELECTRIC ALLOYS WITH IMPROVED THERMOELECTRIC POWER FACTOR

(75) Inventors: JOSEPH P. HEREMANS, UPPER ARLINGTON, OH (US); CHRISTOPHER M. JAWORSKI, COLUMBUS, OH (US); VLADIMIR ANATOLIEVICH KULBACHINSKIY, MOSCOW (RU)

Correspondence Address: KNOBBE MARTENS OLSON & BEAR LLP, 2040 MAIN STREET, FOURTEENTH FLOOR, IRVINE, CA, 92614, US

(73) Assignee: THE OHIO STATE UNIVERSITY, COLUMBUS, OH (US)

(21) Appl. No.: 12/758,651

(22) Filed: Apr. 12, 2010

Related U.S. Application Data
(60) Provisional application No. 61/168,908, filed on Apr. 13, 2009.
(60) Provisional application No. 61/287,669, filed on Dec. 17, 2009.

(51) Int. Cl. H01L 35/34; H01B 1/02; H01B 1/06

(52) U.S. Cl. 136/201; 252/519.13; 252/519.4

(57) ABSTRACT

A thermoelectric material and a method of using a thermoelectric device are provided. The thermoelectric material includes at least one compound having a general composition of (Bi_{1-x-z}SbₓA_{z})ᵤ(Te_{1-y}Se_{y})_{w}. The component A includes at least one Group IV element, and the other components are in the ranges of 0≦x≦1, 0≦y≦1, 0<z≦0.10, 1.8≦u≦2.2, and 2.8≦w≦3.2. The method of using a thermoelectric device can include exposing the thermoelectric material to a temperature greater than about 173 K.

### CROSS-REFERENCE TO RELATED APPLICATIONS

This application claims the benefit of U.S. Provisional Application Nos. 61/168,908, filed Apr. 13, 2009 and 61/287,669, filed Dec. 17, 2009, the entirety of each of which is hereby incorporated by reference.

### BACKGROUND

1. Field

The present application relates generally to thermoelectric materials, and more specifically to thermoelectric devices comprising a semiconductor compound.

2. Description of Related Art

The classical thermoelectric materials used for cooling and heat pumps operating at or near room temperature (300 K) are alloys of composition (Bi₁₋ₓSbₓ)₂(Te_{1-y}Se_{y})₃. The paradigm for this class of alloys is the binary narrow-gap semiconductor Bi₂Te₃. Typically the thermoelectric figure of merit ZT=TS²σ/κ (S is the thermoelectric power or Seebeck coefficient, and σ and κ are the electrical and thermal conductivity, respectively) of binary single-crystal Bi₂Te₃ as well as of some of the (Bi₁₋ₓSbₓ)₂(Te_{1-y}Se_{y})₃ polycrystalline alloys, both n- and p-type, is about 1 at 300 K. The figure of merit of the binary Bi₂Te₃ in single-crystal form reaches about 1 at 300 K only in the directions perpendicular to the trigonal axis, and reaches only about half that value at 300 K along the trigonal axis. ZT values for n-type Bi₂Te₃ are typically a little higher (less than 20%) than for p-type Bi₂Te₃. The optimum doping level for both n- and p-type binary Bi₂Te₃ is about n or p=2×10¹⁹ to 3×10¹⁹ cm⁻³, with more leeway on the p-type side. Advantages of (Bi₁₋ₓSbₓ)₂(Te_{1-y}Se_{y})₃ alloys include that they are polycrystalline so their properties are isotropic, and the sensitivity of the ZT to the doping level is less pronounced than in the binary compound; all of which simplify their preparation. Good p-type alloys are of compositions around Bi₈Sb₃₂Te₆₀ doped to about n=4×10¹⁹ to 7×10¹⁹ cm⁻³ or Bi₁₀Sb₃₀Te₆₀ (more anisotropic) doped to about the same levels. Good n-type materials are of composition Bi₂Se_{0.075}Te_{2.925} doped to about 3×10¹⁹ to 10×10¹⁹ cm⁻³ or Bi₂Se_{0.15}Te_{2.85} doped to about the same electron concentrations. The best values have been obtained at about n=4×10¹⁹ cm⁻³ (H. Scherrer and S. Scherrer, “Bismuth telluride, antimony telluride and their solid solutions”, p 211 in CRC Handbook of Thermoelectrics, D. M. Rowe, editor, CRC Press, Boca-Raton, Fla. (1995)).

Bi₂Te₃ crystallizes in a hexagonal unit cell that is formed by the stacking of layers perpendicular to the trigonal axis. The sequence that is formed is:

—[Te⁽¹⁾—Bi—Te⁽²⁾—Bi—Te⁽¹⁾]—[Te⁽¹⁾—Bi—Te⁽²⁾—Bi—Te⁽¹⁾]—

and has two types of Te atoms, those (Te⁽²⁾) that bond to Bi atoms, and those (Te⁽¹⁾) that bond to each other with weaker Van der Waals bonds. The material has a tendency of forming antisite defects, where Bi atoms can substitute for Te⁽¹⁾ atoms and dope the materials p-type.

Finally, the band structure consists of conduction and valence bands that are have six ellipsoids, with each centered on a mirror plane of the Brillouin zone. The valence bands are centered in the mirror plane of the Brillouin zone and have their main axes in the mirror planes tilted by 25° relative to the crystal axes. Reported band gap E_{g} is E_{g}(0K)=0.16 eV, E_{g}(300 K)=0.13 eV (Sehr, R., Testardi, L. R., J. Phys. Chem. Solids, 23 1219 (1962)), bottom of the conduction band density of states effective mass=0.27 mₑ (H. Kohler, H. Non-Parabolicity of the Lowest Conduction Band in Bi—Te-from Shubnikov-de Haas Effect, Physica Status Solidi (b) 73 (1976)), and top of the valence band density of states effective mass=0.35 mₑ (H. Kohler, Non-parabolicity of the Highest Valence Band of Bi—Te from Shubnikov-de Haas Effect, Physica Status Solidi (b) 74 591 (1976)) (mₑ is the free electron mass) are used here. A second, heavier valence band consisting of six ellipsoids is proposed to lay 20.5 meV below the highest valence band at 2K (Kohler; A. von Middendorf and G. Landwehr “Evidence for a Second Valence Band in p-type Bi—Te-from Magneto-Seebeck and Shubnikov-de Haas Data”, Solid State Commun. 11 203 (1972)).

### SUMMARY

In certain embodiments, a thermoelectric is provided. The thermoelectric material comprises at least one compound having a general composition of (Bi_{1-x-z}SbₓA_{z})ᵤ(Te_{1-y}Se_{y})_{w}, wherein 0≦x≦1, 0≦y≦1, 0<z≦0.10, 1.8≦u≦2.2, 2.8≦w≦3.2. The component A comprises at least one Group IV element.

In some embodiments, the A component comprises tin. In further embodiments, the at least one compound comprises a dopant concentration such that the hole concentration is between about 2×10¹⁹ cm⁻³ and about 7×10¹⁹ cm⁻³ between about 260 K and about 300 K. In even further embodiments, the at least one compound comprises at least one tin-induced resonant level and/or at least one second valence band.

In certain embodiments, a thermoelectric is provided. The thermoelectric material comprises at least one compound comprising a solid solution of bismuth, tellurium, and tin. The at least one compound further comprises at least one tin-induced resonant level, at least one second valence band, and a dopant concentration such that the hole concentration is between about 2×10¹⁹ cm⁻³ and about 7×10¹⁹ cm⁻³ between about 260 K and about 300 K.

In certain embodiments, a method of using a thermoelectric device is provided. The method comprises providing a thermoelectric device comprising a thermoelectric material that comprises at least one compound having a general composition of (Bi_{1-x-z}SbₓA_{z})ᵤ(Te_{1-y}Se_{y})_{w}, wherein 0≦x≦1, 0≦y≦1, 0<z≦0.10, 1.8≦u≦2.2, 2.8≦w≦3.2, and the component A comprises at least one Group IV element. The method further comprises exposing at least a portion of the thermoelectric material to a temperature greater than about 173 K during operation of the thermoelectric device.

### BRIEF DESCRIPTION OF THE DRAWINGS

FIG. 1 illustrates the density of states function g(E) as function of energy E in the valence band or conduction band of a semiconductor with a resonant impurity level. The dashed line represents g(E) for a parabolic band of conventionally doped semiconductor, the excess in g(E) over the range E_{R} represents the region in which the Fermi energy E_{F} has to fall in order to enhance the thermoelectric figure of merit ZT.

FIG. 2 illustrates probable configurations for the valence band of Bi₂Te₃ and Bi₂Te₃:Sn (Kohler, Kulbachinskii, and Zhitinskaya et al.).

FIG. 3 is a plot of SdH traces for Bi₂₋ₘSnₘTe₃ samples, and the inset includes a proposed valence band energy layout.

FIG. 4 is a plot of Pisarenko relation (solid and dashed line) for p-type Bi₂Te₃ as calculated at 300 K. The symbols are for (+) B_{1.9975}Sn_{0.0025}Te₃, (diamond) Bi_{1.9925}Sn_{0.0075}Te₃, (solid circle) Bi_{1.985}Sn_{0.015}Te₃, (solid square) Bi_{1.98}Sn_{0.02}Te₃, and (open star) Bi_{1.95}Sn_{0.05}Te₃. Furthermore, the symbols for Bi₂Te₃ doped with (open square and open diamond) lead (Bergmann et al.; Plechá\check{c}ek et al.), (triangle) germanium (Bergmann et al.), and (solid star) thallium are shown. The inset includes the calculated Pisarenko relation at 80 K as well as experimental points for Bi₂₋ₘSnₘTe₃ as measured.

FIG. 5 is a plot of the Pisarenko relation for p-type Bi₂Te₃ as calculated at 260 K (solid line) and experimental data for (+) Bi_{1.9975}Sn_{0.0025}Te₃, (diamond) Bi_{1.9925}Sn_{0.0075}Te₃ and (circle) Bi_{1.985}Sn_{0.015}Te₃.

FIG. 6 is a plot of resistivity ρ, carrier density p, Seebeck (S), and isothermal transverse Nernst-Ettingshausen (N) coefficients as a function of temperature. The points indicate the measured data while the lines are added to guide the eye. The symbols are: (+) Bi_{1.9975}Sn_{0.0025}Te₃, (diamond) Bi_{1.9925}Sn_{0.0075}Te₃, and (solid circle) Bi_{1.985}Sn_{0.015}Te₃.

FIG. 7 is a plot of the four parameter fits using the degenerate equations. The symbols follow those in FIG. 6.

FIG. 8 is a plot of Seebeck coefficient as a function of temperature for Bi_{1.995}Sn_{0.005}Te₃ exposed to a magnetic field (B) of 7 tesla (T) and 0 T.

### DETAILED DESCRIPTION

Certain embodiments include methods to enhance the thermoelectric figure of merit of Bi₂Te₃ and (Bi₁₋ₓSbₓ)₂(Te_{1-y}Se_{y})₃ (wherein 0≦x≦1 and 0≦y≦1) alloy systems that can be generalized to apply to the industrially relevant alloys described above. The methods and resultant materials are based on the local distortion of the density of states that is either inherent in the band structure of the intrinsic material or induced by resonant impurity levels.

Certain embodiments described herein provide a thermoelectric material that includes at least one compound comprising, consisting, or consisting essentially of a general composition of (Bi_{1-x-z}SbₓA_{z})ᵤ(Te_{1-y}Se_{y})_{w} with 0≦x≦1, 0≦y≦1, 0≦z≦1, 0≦u, 0<u, 0<w, and the component A can include at least one Group IV element. In some embodiments, the at least one compound may include additional elements. For example, the at least one compound may include additional dopants and other alloying elements. The at least one compound may include substantially no impurities, substantially no other elements, and/or substantially no other elements that act as a dopant in the at least one compound. The thermoelectric material may include more than one compound and/or more than one phase.

Furthermore, the thermoelectric material and/or the at least one compound may be doped to be p-type or n-type.

In certain embodiments, the thermoelectric material has the component z in the range of 0<z≦0.10, 0<z≦0.05, 0.0025≦z≦0.05, 0.005≦z≦0.10, 0.005≦z≦0.05, 0<z≦0.01, 0.0005≦z≦0.01, 0.0025≦z≦0.01, or 0.005≦z≦0.01. In further embodiments, the thermoelectric material has the components u and w in the range of 1.8≦u≦2.2 and 2.8≦w≦3.2. In some embodiments, the component x is less than about 0.60. In other embodiments, the component x is in the range of 0.55≦x≦1.

In some embodiments, the A component is selected from the group consisting of tin, lead, and germanium. In further embodiments, the A component comprises, consists, or consists essentially of tin. In other embodiments, the A component comprises, consists, or consists essentially of lead and/or germanium. In one embodiment, the A component comprises, consists, or consists essentially of tin, and the component x is in the range of 0.55≦x≦1. In another embodiment, the A component comprises, consists, or consists essentially of lead and/or germanium, and the component x is in the range of 0≦x≦0.60 or 0<x≦0.60.

The at least one compound can also be described in atomic percentages of elements. For example, the at least one compound can include a first group of elements comprising between about 35 atomic % and about 45 atomic % and a second group of elements comprising between about 55 atomic % and 65 atomic % of the at least one compound. The first group of elements can include bismuth and/or antimony. The first group can further include at least one Group IV element. For example, the Group IV element can include tin. The Group IV can be greater than zero and less than about 5 atomic % of the at least one compound. In some embodiments the Group IV is greater than about 0.05 atomic % or greater than about 0.1 atomic % of the at least one compound. In further embodiments, the Group IV is less than about 2 at. %, less than about 1 at. %, less than about 0.8 at. %, or less than about 0.5 at. % of the at least one compound.

The dopant concentration can be controlled for the at least one compound to control the carrier concentration (e.g., electron concentration and hole concentration). For example, the at least one compound can include a dopant concentration such that the hole concentration is greater than about 4×10¹⁹ cm⁻³ as measured by Hall effect at 260 K. In certain embodiments, the at least one compound includes a dopant concentration such that the hole concentration is between about 2×10¹⁹ cm⁻³ and about 10×10¹⁹ cm⁻³ as measured by Hall effect at 300 K, between about 2×10¹⁹ cm⁻³ and about 8×10¹⁹ cm⁻³ as measured by Hall effect at 300 K, between about 2×10¹⁹ cm⁻³ and about 7×10¹⁹ cm⁻³ as measured by Hall effect at 300 K, between about 3×10¹⁹ cm⁻³ and about 7×10¹⁹ cm⁻³ as measured by Hall effect at 300 K, or greater than about 2×10¹⁹ cm⁻³ as measured by Hall effect at 300 K. In further embodiments, the at least one compound includes a dopant concentration such that the hole concentration is between about 2×10¹⁹ cm⁻³ and about 10×10¹⁹ cm⁻³ as measured by Hall effect between about 260 K and about 300 K, between about 2×10¹⁹ cm⁻³ and about 8×10¹⁹ cm⁻³ as measured by Hall effect between about 260 K and about 300 K, between about 2×10¹⁹ cm⁻³ and about 7×10¹⁹ cm⁻³ as measured by Hall effect between about 260 K and about 300 K, or between about 3×10¹⁹ cm⁻³ and about 7×10¹⁹ cm⁻³ as measured by Hall effect between about 260 K and about 300 K.

The at least one compound can include at least one tin-induced resonant level and/or at least one second valence band. In certain embodiments, a thermoelectric material comprising at least one compound comprising bismuth, tellurium, and tin, the at least one compound comprises at least one tin-induced resonant level and/or at least one second valence band.

As described above, the at least one compound can be doped with at least one Group IV element. In certain such embodiments, the at least one Group IV element is able to have a fluctuating valence. One example of a Group IV element able to have a fluctuating valence is tin (e.g., Sn²⁺ to Sn⁴⁺). In certain embodiments, the resonant level is not optimally located (see, e.g., V. A., Kulbachinskii, Thermoelectric Power and Scattering of Carriers in Bi₂₋ₓSnₓTe₃ with Layered Structure, Physical Status Solidi (b) 199 505 (1997)). Examples of Group IV elements compatible with certain embodiments described herein include, but are not limited to, tin, lead, and germanium. In certain various embodiments, the atomic concentration of the at least one Group IV dopant atoms is in a range between about 0.2 atomic % and about 5 atomic %, between about 0.4 atomic % and about 2 atomic %, between about 0.5 atomic % to about 2 atomic %, between about 0.4 atomic % and about 1 atomic %, or between about 0.4 atomic % and about 0.8 atomic %, either as a substitute for the bismuth, antimony, tellurium, or selenium atoms, or in addition to the bismuth, antimony, tellurium, or selenium atoms.

In one embodiment, the at least one compound includes at least one solid-state solution of tin in Bi₂Te₃ in the composition range Bi₂₋ₘSnₘTe₃, with 0.0025≦m≦0.05. In certain embodiments, the alloy has a tin content from 0.05 to 1 atomic % per 5-atom formula unit. To convert between atomic % and m in the 5-atom formula unit, multiply or divide by 20. For example, 0.30 atomic % is m=0.015 and 0.05 atomic % is m=0.0025. For (Bi₁₋ₓSbₓ)₂(Te_{1-y}Se_{y})₃ alloys or the formulation Bi₂₋ₘSnₘTe₃, the 5 atoms are 2 Bi+3 Te or equivalent. In another embodiment, the alloy includes at least one solid-state solution of tin in at least one (Bi₁₋ₓSbₓ)₂(Te_{1-y}Se_{y})₃ alloy, with 0≦x≦1 and 0≦y≦1 and tin content from 0.05 to 1 atomic % per 5-atom formula unit.

In certain embodiments, Bi₂Te₃ with tin compared to Bi₂Te₃ has a higher resistivity below about 250 K and a lower resistivity above about 250 K. In further embodiments, the Nernst coefficient decreases as tin concentration increases.

In certain embodiments, a method of using a thermoelectric device is provided. The thermoelectric device can include a thermoelectric material such as those described herein. For example, a thermoelectric material comprising at least one compound having a general composition of (Bi_{1-x-z}SbₓA_{z})ᵤ(Te_{1-y}Se_{y})_{w} with 0≦x≦1, 0≦y≦1, 0<z≦0.10, 1.8≦u≦2.2, 2.8≦w≦3.2, and the component A including at least one Group IV element can be provided. The method can include exposing at least a portion of the thermoelectric material and/or the at least one compound to a temperature greater than about 173 K during operation of the thermoelectric material and/or thermoelectric device. In further embodiments, exposed to a temperature in a range between about 173 K and about 500 K, exposed to a temperature in a range between about 173 K and about 400 K, exposed to a temperature in a range between about 200 K and about 500 K, exposed to a temperature in a range between about 200 K and about 400 K, at least a portion of the thermoelectric material is exposed to a temperature in a range between about 280 K and about 320 K, exposed to room temperature, exposed to a temperature greater than about 250 K, exposed to a temperature greater than about 260 K, exposed to a temperature greater than about 280 K, or exposed to a temperature greater than about 350 K during operation of the thermoelectric material and/or thermoelectric device.

### Examples and Further Description of Embodiments

To illustrate the advantages of thermoelectric materials described herein, experimental samples of embodiments of thermoelectric materials are described below, and are also compared to other thermoelectric materials. Furthermore, without being bound by theory, mechanisms for improvements in thermoelectric properties (e.g., ZT) are also described.

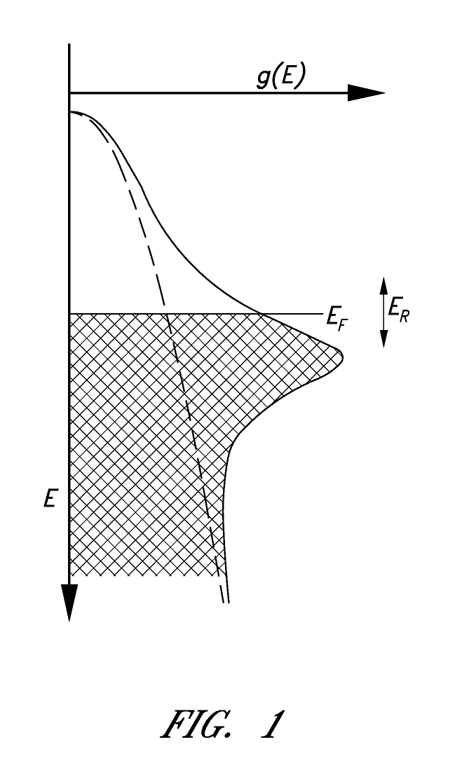

In certain embodiments, the (Pb₁₋ₓSnₓ)(Te_{1-y}Se_{y}) alloy system of thermoelectric semiconductors is suitable for applications around 500° C., which has applications in the thermoelectric generator business. The paradigm for the (Pb₁₋ₓSnₓ)(Te_{1-y}Se_{y}) system is the binary narrow-gap semiconductor PbTe. A doubling of the thermoelectric figure of merit ZT of p-type PbTe above 700 K has been recently demonstrated (J. P. Heremans et al., Science 321, 554 (2008)) in thallium-doped material, PbTe:Tl. The effect has been proposed to come about because an electronic energy level of the thallium atoms resonates with the valence band of PbTe. This creates an excess density of states, g(E), at a specific energy of about 60 meV below the valence band edge, which in turn gives a thermoelectric power at that carrier concentration about three times higher than that of similarly-doped p-type PbTe. The details of the ZT enhancing mechanism are described in J. P. Heremans et al., Science 321, 554 (2008). It is based on the thallium energy level forming a “resonant impurity state” which distorts the density of states function of energy, g(E), compared to the normal E^{1/2} which forms parabolic bands in three dimensions into a spike-like function (see FIG. 1).

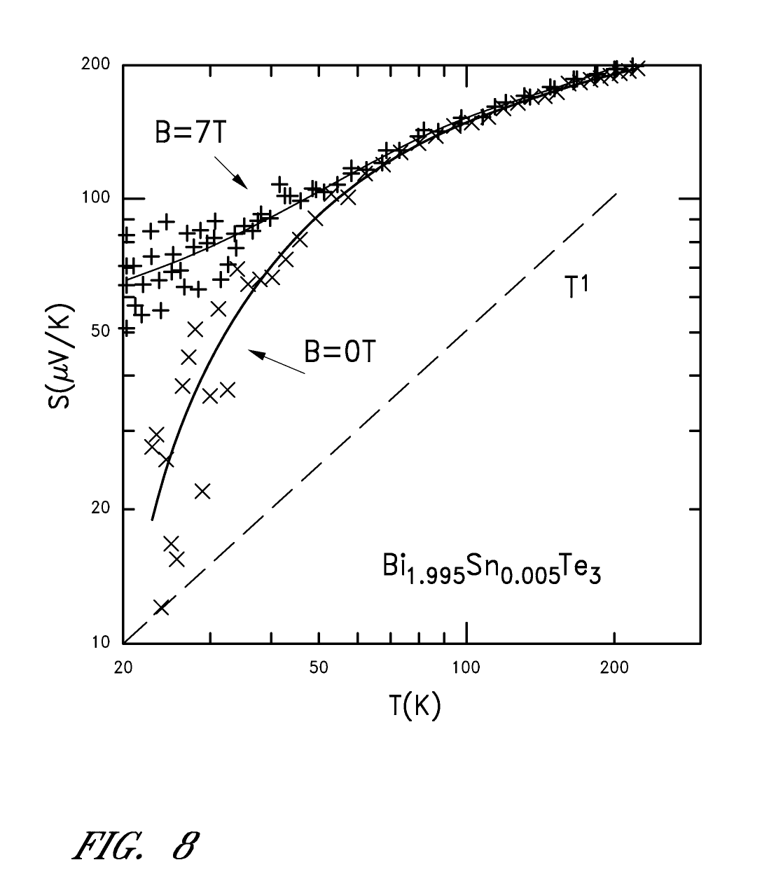

The concept of an impurity-induced resonant state, also known as a “virtual bound state,” was introduced by Friedel (J. Friedel, Can. J. Phys. 34, 1190 (1956)) as a bound state with a positive energy with respect to the band edge, i.e. with the same energy as an extended state. If it can resonate with a component of that extended state, it builds up two extended states of slightly different energies; these in turn have the same energies as the extended states with whom they will resonate, and so on, until an excess density of states arises over a narrow energy range in the band of the host material. Virtual bound states in metals have been shown to lead to an increase in thermoelectric power of the host metal by a mechanism now known as resonant scattering theory (P. de Faget de Casteljau and J. Friedel, J. Phys. Radium 17, 27 (1956); A. Blandin and J. Friedel, ibid. 20, 160 (1959)); this evolved into the Kondo effect (J. Kondo, Prog. Theor. Phys. 34, 372 (1965)) when applied to dilute alloys of magnetic impurities in metals. Resonant levels (B. A. Volkov et al., Phys. Usp. 45, 819 (2002)) and resonant scattering (V. I. Kaidanov et al., Sov. Phys. Semicond. 26, 113 (1992); Yu. I. Ravich, in CRC Handbook on Thermoelectrics edited by D. M. Rowe, CRC Press, Boca Raton, Fla., (1995)) were also observed in semiconductors such as PbTe. Even if some metals can have Kondo temperatures in excess of 300 K, acoustic and optical phonon scattering far exceeds resonant scattering at all but cryogenic temperatures in most metals and in all semiconductors. Ravich recognizes that resonant scattering is not a practical mechanism for enhancing the thermoelectric properties of semiconductors above the cryogenic range. FIG. 8 plots Seebeck coefficient (S) as a function of temperature (T). T¹ represents expected values with resonant levels. B=0 T represents a magnetic field (B) of 0 tesla (0 T) applied to Bi_{1.995}Sn_{0.005}Te₃ so that electron scattering can occur. B=7 T represents a magnetic field of 7 T applied to Bi_{1.995}Sn_{0.005}Te₃ so that electron scattering is removed. Contrasting with the resonant scattering concept, Mahan and Sofo (G. D. Mahan and J. O. Sofo, Proc. Natl. Acad. Sci. U.S.A. 93, 7436 (1996)) suggest that the thermopower and the thermoelectric figure of merit can be boosted intrinsically by the excess density of states itself. Because this mechanism does not involve any scattering, it is in essence temperature independent (except for the temperature dependence of the band structure itself), (V. Jovovic et al., J. Appl. Phys. 103, 053710 (2008)) and thus suitable for enhancing the figure of merit in practical thermoelectric materials at and above room temperature. It is this mechanism that was shown to be at work in high-ZT PbTe:Tl (J. P. Heremans et al., Science 321, 554 (2008)). In certain embodiments described herein, tin has been identified as creating a resonant level capable of a similar enhancement at room temperature in the classical thermoelectric semiconductor, Bi₂Te₃, which is the parent material for alloys widely used in Peltier cooling and heating. Experimental proof of this realization, however, is complicated by the lower valence band that is located much closer in energy to the upper valence band than that of PbTe.

In certain embodiments, a similar g(E) can be obtained in Bi₂Te₃, and this can lead to an enhanced ZT in that material system. In some embodiments, Bi₂Te₃ can be doped p-type with extrinsic group IV atoms (e.g., germanium, tin, and lead). The impurity concentration of the acceptors does not match one-to-one with the excess hole or electron concentration, with 1.4-1.7 holes introduced for one lead atom depending on the occupied lattice site at low tin concentrations (M. K. Zhitinskaya, S. A. Nemov and T. E. Svechnikova, Physics of the Solid State 40 1297 (1998) [Fiz. Tverd. Tela, 40 8 1998]). Further, it is observed that hole concentration of tin doped samples has a lesser dependence once the Fermi level gets pinned to the tin level. Zhitinskaya (M. K. Zhitinskaya, S. A. Nemov and T. E. Svechnikova, Physics of the Solid State 40 1297 (1998) [Fiz. Tverd. Tela, 40 8 1998]) reports that from the range of tin impurities of 1.2×10¹⁹ cm⁻³ to 6×10¹⁹ cm⁻³, the hole concentration only varies from 2×10¹⁸ cm⁻³ to 5×10¹⁸ cm⁻³. This corresponds to a doping efficiency of 0.06 holes per tin atom. This is thought to occur because tin, due to its higher electronegativity, helps to prevent the construction of antisite defects. At low atomic concentrations (<0.2 at %), tin atoms primarily occupy Te⁽²⁾ sites (M. K. Zhitinskaya, S. A. Nemov, T. E. Svechnikova, L. N. Luk'yanova, P. P. Konstantinov, and V. A. Kutasov, Physics of the Solid State, 45 1251 (2003) [Fizika Tverdogo Tela, Vol 45, No. 7, 2003]). Between 0.2 at % and 1 at %, tin atoms begin to occupy the Te⁽¹⁾ sites. These tin atoms are neutral with respect to the lattice, but accept electrons (M. K. Zhitinskaya, S. A. Nemov, T. E. Svechnikova, L. N. Luk'yanova, P. P. Konstantinov, and V. A. Kutasov, Physics of the Solid State, 45 1251 (2003) [Fizika Tverdogo Tela, Vol 45, No. 7, 2003]) from higher lying valence states and have a total hole concentration of <10¹⁹ cm⁻³.

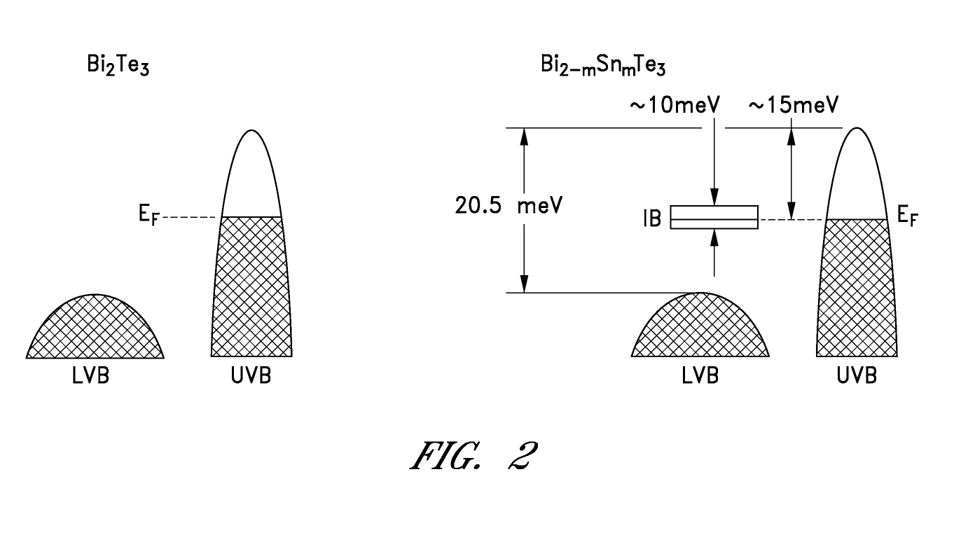

In 1989, Kulbachinskii and co-workers (V. A. Kul'bachinskii, N. E. Klokova, S. Ya. Skipidarov, et al., Vestn. Mosk. Univ., Ser. 3: Fiz. Astron. 30 (3), 68 (1989)) first described (N. Miyajima, M. Sakaki, N. Neghishi, M. Inoue, V. A. Kulbachinskii, A. Y. Kaminskii and K. Suga, J. Low Temp. Physics 123 219 (2001)) a quantization of the Hall effect that indicates the presence of an additional reservoir of charge carriers in tin-doped p-type Bi₂Te₃ (labeled Bi₂Te₃:Sn) single crystals. Additionally, Kulbachinskii reported that tin may form a resonant level in Bi₂Te₃ (V. A., Kulbachinskii. Thermoelectric Power and Scattering of Carriers in Bi₂SnₓTe₃ with Layered Structure, Physical Status Solidi (b) 199 505 (1997); Kulbachinskii, V. A., Valence-Band Energy Spectrum of Solid Solutions, Physical Review B, 1994, Vols. 50, 23, 16921). Also notable is that the introduction of tin helps to stabilize the Seebeck coefficient of single crystals of Bi₂Te₃ grown by the Czochralski method (M. K. Zhitinskaya, S. A. Nemov, T. E. Svechnikova, P. Reinshaus, and E. Müller, Semiconductors, Vol. 34, 1363 (2000) [Fizika i Tekhnika Poluprovodnikov, Vol. 34, No. 12, 2000, pp. 1417-1419]). By analogy with the states induced by thallium in PbTe, Kulbachinskii identified this additional reservoir of carriers as being due to resonant states induced by tin in Bi₂Te₃. It is assumed that it is the tin atoms on the Te⁽¹⁾ sites that act as resonant levels (M. K. Zhitinskaya, S. A. Nemov, T. E. Svechnikova, L. N. Luk'yanova, P. P. Konstantinov, and V. A. Kutasov, Physics of the Solid State, 45 1251 (2003) [Fizika Tverdogo Tela, Vol 45, No. 7, 2003]). The band of tin impurity states lies near the edge of the second band, with Kulbachinskii reporting that it is 15 meV below the top of the highest band at 2K. The band was calculated to be about 10 meV wide (M. K. Zhitinskaya, S. A. Nemov and T. E. Svechnikova, Physics of the Solid State 40 1297 (1998) [Fiz. Tverd. Tela, 40 8 1998]) using degenerate statistics and the four transport coefficients (Seebeck, Hall, Nemst, and resistivity), leading to the picture of the band structure shown in FIG. 2.

Zhitinskaya (M. K. Zhitinskaya, S. A. Nemov and T. E. Svechnikova, Physics of the Solid State 40 1297 (1998) [Fiz. Tverd. Tela, 40 8 1998]) noticed the similarity between the transport properties of Bi₂Te₃:Sn and those of PbTe:Tl. She further hypothesizes that certain tin concentrations create resonant states that increase the thermoelectric power factor S²σ and thus ZT, by means of the mechanism Ravich labeled “resonant scattering” (Yu. I. Ravich, “Selective carrier scattering in Thermoelectric Materials”, p 67 in CRC Handbook of Thermoelectrics, D. M. Rowe, editor, CRC Press, Boca-Raton, Fla. (1995)). However, this mechanism is not applicable (J. P. Heremans et al., Science 321 554 (2008)). In a further publication, Zhitinskaya and coworkers (M. K. Zhitinskaya, S. A. Nemov, M. Yu. Nikulina, T. E. Svechnikova, E. Mueller and D. Platzek, “Properties of electron and phonon sub-systems of tin-doped bismuth telluride-based solid solutions”, Akademia Gomiczo Hutnicza w Krakowie, Proceedings of the 8th European Workshop on Thermoelectrics, Krakow, Poland (2004)) claimed that n-type tin-doped Bi₂Te₃ alloys can reach ZT values of 1.1 to 1.2 at 340 K to 370 K (the temperature at which the ZT value of most Bi₂Te₃-based alloys peaks), and ascribed the properties of n-type material to a resonant state in the valence band. The relation between the resonant state and an improvement in ZT is thus at best confused, and these arguments teach against continuing this avenue of research.

The situation regarding resonant levels in Bi₂Te₃ is not as clear as it is in PbTe:Tl, mostly because the effects are much smaller, which in turn is due to the fact that the energy separation between the level of tin in Bi₂Te₃ is only 15 meV below the valence band edge, whereas the thallium level in PbTe is 60 meV below the conduction band edge (see FIG. 2). This is important because the thermal energy at 300 K is k_{B}T=25 meV, so the electronic properties at useful operating temperatures sample all three bands shown in FIG. 2.

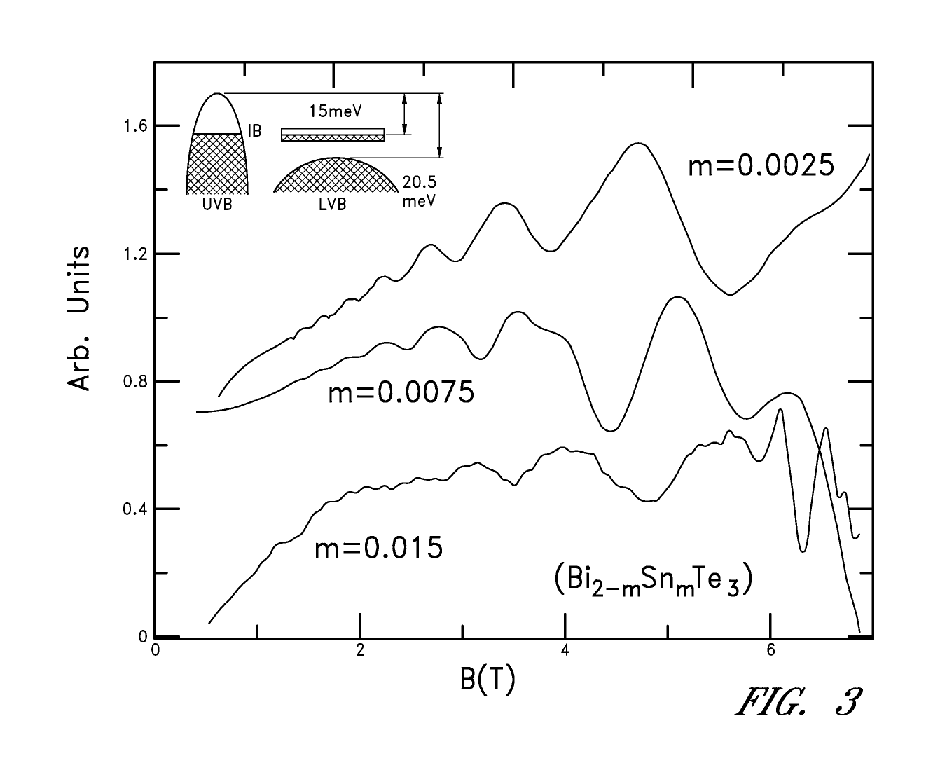

Bi₂Te₃ has upper valence bands (UVBs) which have Fermi surfaces that consist of six ellipsoidal pockets in k space (H. Köhler, Phys. Status Solidi B 74, 591 (1976)), centered in the mirror plane of the Brillouin zone lying along (0.3-0.5) |ΓX| direction (Landolt-Bornstein, Group III, Vol. 17, edited by K. H. Hellwege and O. Madelung, Springer-Verlag, Berlin, (1983); the integrated density of states mass is the density of states mass of each pocket of the Fermi surface, multiplied by the number of pockets to the power ⅔), and have an integral density of states (DOS) effective mass m^{*}_{d}=0.35 mₑ (Landolt-Bornstein). A lower, heavier valence band (LVB), consisting of six ellipsoids, has been shown to exist 20.5 meV below the UVB in k space at (0.3-0.4) |ΓA| (H. Köhler, Phys. Status Solidi B 74, 591 (1976)). Bi₂Te₃ can be doped p-type with extrinsic atoms such as germanium, tin, or lead or n-type with indium, chlorine, or iodine. It is known that tin forms a resonant state at 15 meV below the top of the UVB at 2 K (V. A. Kulbachinskii et al., Phys. Status Solidi 150, 237 (1988) b.; V. A. Kulbachinskii et al., Phys. Rev. B 50, 16921 (1994) and “stabilizes” the Seebeck coefficient (S) of single crystals of Bi₂Te₃ (V. A. Kulbachinskii et al., Phys. Status Solidi 199, 505 (1997) b.). The inset in FIG. 3 illustrates the suggested energy level layout. Zhitinskaya (M. K. Zhitinskaya et al., Proceedings of the 16th International Conference on Thermoelectricity, IEEE 1997 (unpublished) p. 97; M. K. Zhitinskaya et al., Phys. Solid State 40, 1297 (1998)) indeed reported an enhancement of the thermopower at a given hole concentration near liquid nitrogen temperature, but ascribed it to resonant scattering, which suggested that this effect would be limited to low temperatures (M. K. Zhitinskaya et al., Proceedings of the European Thermoelectric Society Meeting, (2004) (unpublished) http://galaxy.uci.agh.edu.pl/˜ets2004/proceedings/Zhitinskaya.PDF; report measurements up to 400 K on tin-doped Bi₂Te₃ single crystals, but mention only “a modified temperature dependence of the transport coefficients” besides the presence of resonant states).

Improvements in the ZT can arise from either the tin induced resonant level, or from the second valence band itself. Indeed, referring to FIG. 1, it is the distortion of the density of states g(E) in the region E_{R} that results in an enhanced Seebeck coefficient at a given carrier concentration. The shape of the function g(E) at energies much below E_{F} is of little importance. If tin induces a resonant level, the shape of g(E) will be such as shown in FIG. 1. If the presence of the second, heavy, valence band is used, the shape of g(E) will be similar in the region E_{R}, but does not have a maximum, and continues to increase monotonically at energies much below E_{F}. Therefore, certain embodiments include the use of the tin-induced resonant level simultaneously with the second valence band to improve the ZT of p-type Bi₂Te₃. In further embodiments, tin is a resonant impurity that distorts the valence band dispersion of Bi₂Te₃ and strongly enhances its thermoelectric power at room temperature.

Single crystals of Bi₂Te₃:Sn were formed and measurements were carried out of the electrical resistivity, Hall effect, Seebeck effect, Nemst effect, and as well as of quantum oscillations in the electrical resistivity, in the magneto-Seebeck effect (the Shubnikov-de Haas effect) and in the specific heat (magnetothermal oscillations). Single crystals of tin-doped bismuth telluride (Bi₂₋ₘSnₘTe₃) with nominal concentrations in the melt of m=0.0025, 0.0075, and 0.015 were grown using a modified Bridgeman technique. These single crystals were used for both thermoelectric and Shubnikov-de Haas measurements. For example, purity of 5N or better of bismuth, tellurium, and tin were sealed under high vacuum in quartz ampoules. The ampoules were heated to 620° C. to melt the elements. The ampoules were rocked to ensure uniformity of the liquid melt. The ampoules were loaded into a Bridgeman type setup and then pulled into an environment at a temperature of 25° C. For one sample, the ampoule was pulled 10 mm in 24 hr. Samples were generally pulled at a rate of about 2 mm/hr or less. Three additional single crystals were grown (one with x=0.02, and two with x=0.05) and were used only for the thermoelectric measurements. Nominal concentrations were heated to 700° C., rocked, cooled to 600° C., and then pulled in a Bridgeman-type apparatus.

The thermoelectric properties generally correlated more with the Hall data than with the actual amount of tin put in the melt. The samples' long axis (index 1) were in the plane perpendicular to the (001) direction. SdH oscillations were measured in both resistivity and Hall coefficient at 1.9 K with the magnetic field oriented along the trigonal direction H₃∥<001> and swept from −7 T to 7 T, and deduce the cross-sectional areas of the Fermi surfaces. Four thermomagnetic and galvanomagnetic coefficients were measured as in J. P. Heremans et al., J. Appl. Phys. 98, 063703 (2005). The isothermal transverse Nernst-Ettingshausen coefficient N[=N₂₁(H₃)], was measured from 77 to 400 K while Hall coefficient R_{H}=[R_{H21}(H₃)], thermopower S(=S₁₁), and resistivity ρ(=ρ₁₁) were measured from 2 to 400 K. From these measurements, the Fermi level, carrier mobility, effective mass, and scattering exponent at each temperature was calculated (J. P. Heremans et al., Phys. Rev. B 70, 115334 (2004)). A possible source of error on the measurements of Seebeck coefficient is related to the difficulty in measuring voltage and temperature at precisely the same location. Copper/constantan thermocouples welded to the sample were used to measure temperatures, and the same copper wires were used to measure the voltage. Care was taken to minimize the size of the contact, and a wire of 25 μm diameter was used to limit the wire heat draining capability. The error on S₁₁ was estimated to be on the order of 3%. A possible source of error on measurements of N₂₁(H₃), R_{H21}(H₃), and ρ₁₁ was the inaccuracy in the measurement of the dimensions of the sample; the errors on N₂₁(H₃) and R_{H21}(H₃), were on the order of 5%, while that on ρ_{H} was <10%. The accuracy on the periods of the SdH oscillations was limited by the thermal smearing of the oscillations. The inaccuracy was on the order of 5% for the low-doped samples, but 10% for the highest-doped one which had a lower mobility.

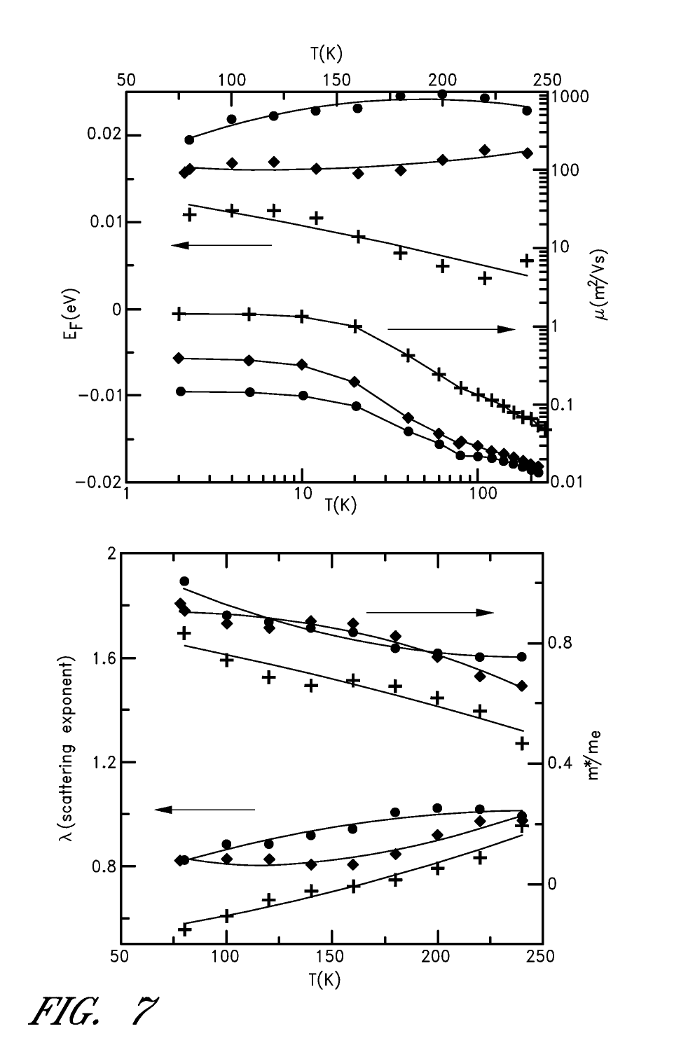

The SdH oscillations in ρ₁₁ are shown in FIG. 3 and are periodic in 1/H₃. The amplitude of the SdH oscillations first increase with m from m=0.0025 to m=0.0075 and then decrease again for m=0.015. The trace for m=0.015 has been magnified by 10⁵, and the background subtracted in FIG. 3. Some peaks are visibly split in the raw traces, and the Fourier transforms of ρ₁₁(1/H₃) show two “frequencies” in 1/ρ (1/H3), as shown in Table I. Table 1 lists tin concentrations (m) and magnetic field oscillation frequencies [Δ(1/H)]⁻¹ (T) and the corresponding Fermi surface areas A_{F} for the three tested alloys. By comparison with the full calculated Landau level spectrum (N. Miyajima et al., J. Low Temp. Phys. 123, 219 (2001), the second frequency is a 2nd harmonic due to spin-splitting. The first period corresponds to a cross-sectional area of the Fermi surfaces which is also shown in Table I. FIG. 7 of V. A. Kulbachinskii et al., Phys. Rev. B 50, 16921 (1994) plots the hole densities measured by Hall effect as a function of the Fermi energy deduced from the measured areas of the Fermi surface in Table I by using the UVB cyclotron masses (H. Köhler, Phys. Status Solidi B 74, 591 (1976)). Results were compared to those from the data of V. A. Kulbachinskii et al., Phys. Rev. B 50, 16921 (1994) and V. A. Kulbachinskii et al., Phys. Rev. B 50, 16921 (1994). Kohler used this procedure and showed that there is a marked increase in carrier density when the Fermi level reaches 20.5 meV below the UVB, which is the evidence for the existence of the LVB. The mass parameters for this band have not been determined as of yet; however, Kohler indicates that the integral DOS mass of the LVB exceeds 1.25 mₑ for Bi₂Te₃ without tin. Kulbachinskii (V. A. Kulbachinskii et al., Phys. Status Solidi 150, 237 (1988) b; V. A. Kulbachinskii et al., Phys. Status Solidi 199, 505 (1997) b) shows a second deviation in tin doped Bi₂Te₃ when the Fermi energy reaches 15 meV below the top of the UVB. Here, taking the second frequency as a harmonic, the Fermi level was calculated using the same procedure and the present experimental points fall in accordance with the points shown by Kulbachinskii (V. A. Kulbachinskii et al., Phys. Rev. B 50, 16921 (1994)). A different conclusion could mathematically be arrived at if the second frequency was assumed to correspond to a second series of pockets on the Fermi surface, which is not physical, but this ambiguity is lifted with thermoelectric and thermomagnetic measurements.

TABLE 1

| | [Δ(1/H)]⁻¹ | A_{F} |
|---|---|---|
| Bi₂₋ₘSnₘTe₃ | (T) | (m⁻²) |
| m = 0.0025 | 12.15 | 1.16 × 10¹⁷ |
| | 24.2 | |
| m = 0.0075 | 11.3 | 1.09 × 10¹⁷ |
| | 22.3 | |
| m = 0.015 | 13.2 | 1.25 × 10¹⁷ |
| | 27.8 | |

The SdH results can be analyzed two ways: either the two oscillation frequencies arise from two different sets of degenerate sections of the Fermi surface, or the second frequency is a harmonic and there is just one set of Fermi surface sections. Taking the second frequency as real, it would correspond to cross-sections of the Fermi surface that are consistent with the LVB of H. Köhler, Phys. Status Solidi B 74, 591 (1976). If this hypothesis is pushed further, the Fermi level, total Hall carrier density, and SdH carrier density and effective mass of the UVB could be used to deduce the density of carriers left in the LVB and their masses. The LVB hole density calculated under that hypothesis would be 2 to 5 times larger than that of the UVB, and the calculated LVB masses would be approximately 1.5 to 3 mₑ, which is heavier than previously suggested (H. Köhler, Phys. Status Solidi B 74, 591 (1976)). Furthermore, the LVB masses would appear to depend on tin concentration. This mathematical possibility is unphysical because it contradicts the calculations based on the four transport parameters (Fermi level, effective mass, scattering exponent, and mobility), and because the second frequency can be assigned to spin splitting (N. Miyajima et al., J. Low Temp. Phys. 123, 219 (2001).

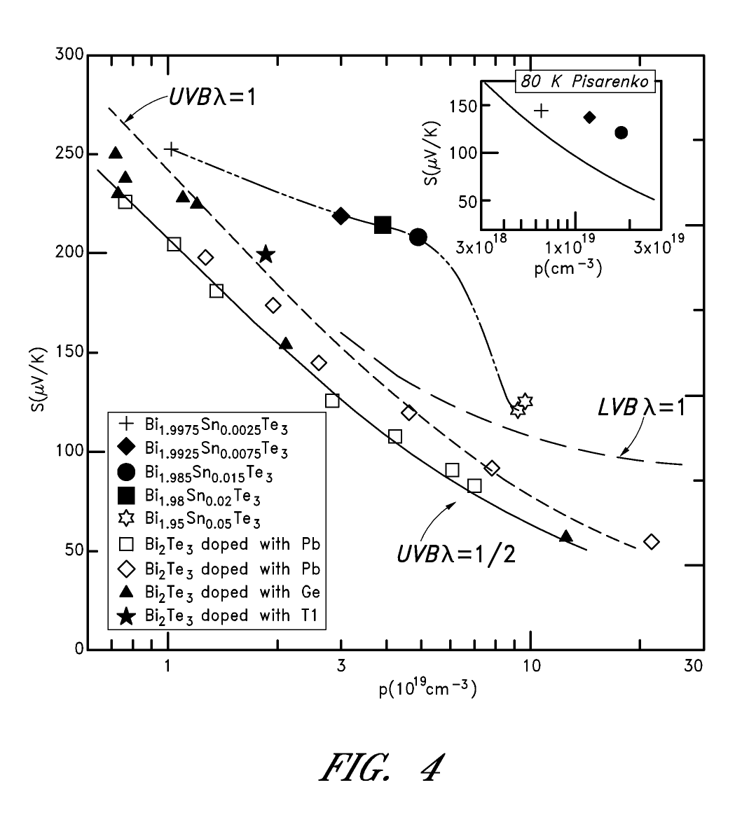

As shown in the case of PbTe:Tl, a resonance is positioned such as to increase the power factor, which is the product of the square of the Seebeck coefficient (S²) times the electrical conductivity (σ), and which can exhibit an increase in the Seebeck coefficient at a given carrier concentration over that which is due to conventionally-doped material. The relationship between carrier density n and Seebeck coefficient S(n) (where n is the density of holes in p-type material) is called the Pisarenko relation. The Pisarenko relation was derived for Bi₂Te₃ at 300 K and is plotted in FIG. 4. Also shown in FIG. 4 are experimental data points of conventionally doped material contrasted with those measured on tin-doped material (+).

The fundamental relation between the S and the carrier density p in each semiconductor band was called the “Pisarenko relation” by Ioffe (A. F. Ioffe, Physics of Semiconductors (Academic, New York, 1960)). The Pisarenko relation forms a reference to compare S for a carrier concentration and scattering mechanism. The thermopower of degenerately doped Bi₂Te₃ is isotropic and S₁ equals the scalar partial hole coefficient S(p). The Seebeck coefficient (S) of Bi₂Te₃ is anisotropic in general, but the partial Seebeck coefficients of each electron or hole pocket of the Fermi surface are scalars. The anisotropy arises from the fact that the total Seebeck coefficient is an average of the partial coefficients of each pocket weighted by the partial conductivities of those pockets, which are anisotropic. S₁₁ is dominated by the partial hole Seebeck coefficient S(p) in moderately p-type material. The partial hole Seebeck coefficient S(p) for p-type Bi₂Te₃ was calculated as lines in FIG. 4, assuming that the relaxation time follows a power law of energy τ=τ₀E^{λ}, where λ is the scattering exponent (J. P. Heremans et al., Phys. Rev. B 70, 115334 (2004)). S(p) for two scattering mechanisms was calculated, optical scattering (λ=0.5) and ionized impurity scattering, (λ=1) at 300 and 80 K (inset) using an integral density of states effective mass of m*_{d}=0.35 mₑ of the UVB. An estimate of the influence of the LVB is illustrated in FIG. 4 as a dashed line calculated with λ=1 and m*_{d, LVB}=1 mₑ; this can be quite inaccurate because the effective mass of the LVB is not well known (H. Köhler, Phys. Status Solidi B 74, 591 (1976)) and also because the temperature dependence of the band structure is not known and not taken into account. Literature data taken on p-type Bi₂Te₃ (G. Bergmann, Z Natuforsch. 18a, 1169 (1963); T. Plechá\check{c}ek et al., Philos. Mag. 84, 2217 (2004)) at 300 K was also included. The data follow a trace for the UVB and ignore the effect of the LVB; the relative position of the two bands may have a temperature dependence that is not known to date, and that the LVB probably moved with increasing temperature to a lower energy level with respect to the top of the UVB at 300 K than Kohler's measurements at 4.2 K indicate. The scattering exponent that best fits the Seebeck data changes from 0.5 to 1 with increasing carrier concentration, which indicates a progressive change from optical to ionized impurity scattering. Upon placing the data measured at 300 K the Bi₂₋ₘTe₃Snₘ samples onto the Pisarenko relation in FIG. 4, a marked departure from that of the other similarly doped samples is shown, which indicates the presence of a resonant level. The x=0.015 sample has a Seebeck coefficient double that of samples doped to similar hole concentrations without tin. The calculated 80 K Pisarenko relation and our experimental data points were included, which demonstrate an increase of 50% to 250% in Seebeck coefficient over that of similarly doped Bi₂Te₃.

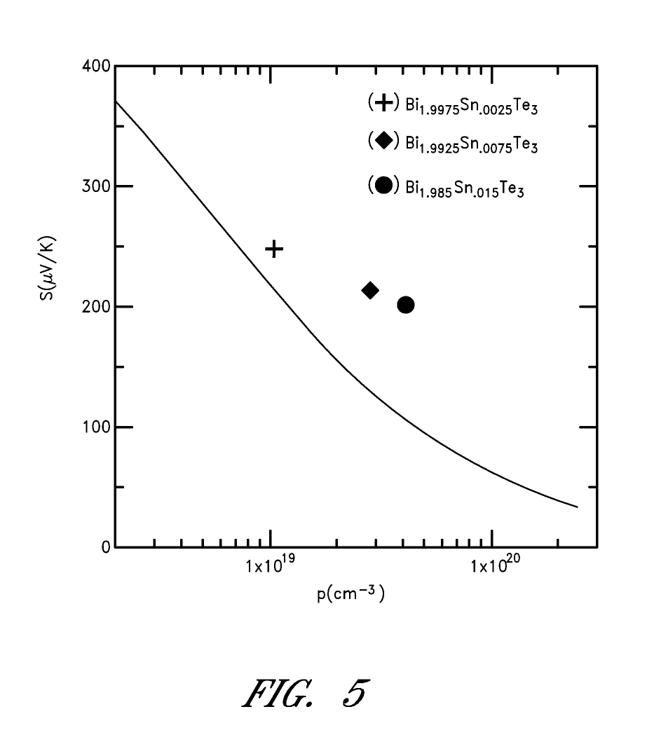

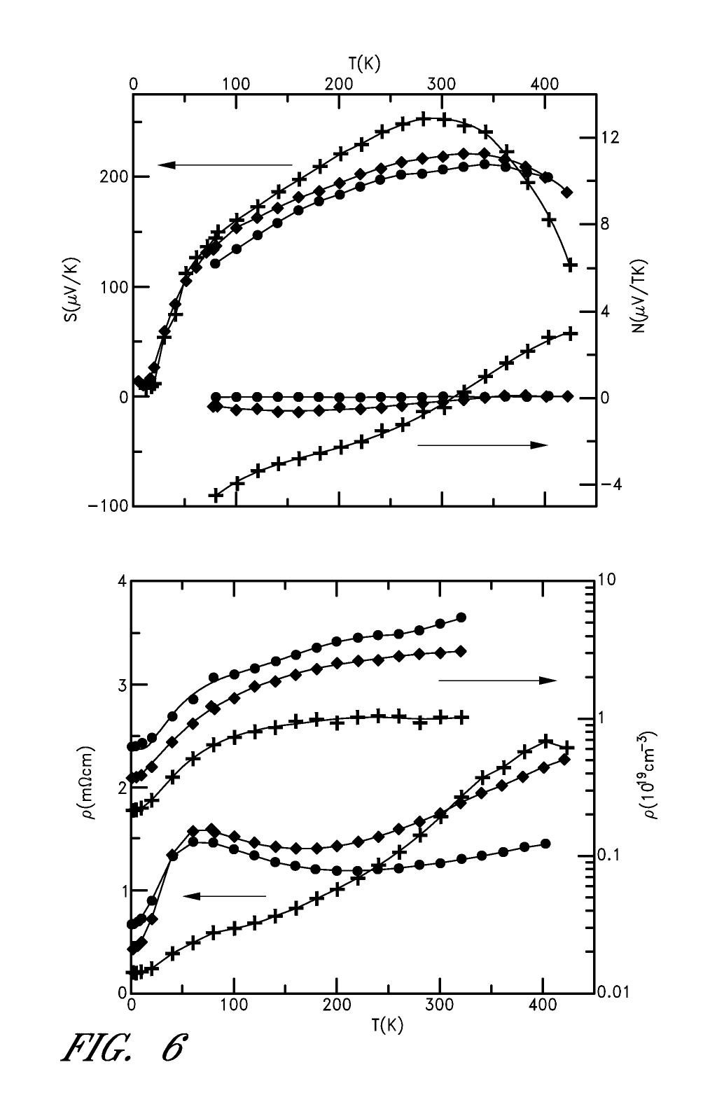

The Seebeck coefficient of heavily doped semiconductors is expected to increase linearly with temperature up to a temperature where thermal excitations across the band gap create a number of minority carriers (e.g. electrons in p-type material) that make it saturate and decrease, as shown in FIG. 6. Experimentally, the temperature-dependence of the Seebeck coefficient of the tin-doped p-type material is shown in FIG. 6, and displays two prominent features: (1) a strong excess in Seebeck that peaks at about 80 K, and (2) a turnover of the Seebeck coefficient, due to the appearance of minority electrons, that starts at about 300 K. A more relevant illustration of the excess in Seebeck coefficient in Bi₂Te₃:Sn is shown by the Pisarenko relation at about 260 K, as shown in FIG. 5.

A determining factor is the actual p-type doping level, which should be sufficiently high to reach not only the tin-induced resonant level at the operating temperature (>300 K), but also to sufficiently probe the second band and minimize compensation of the hole-Seebeck coefficient by the thermal excitation of minority electrons. From FIG. 5, this doping level has not been reached in the samples; the maximum hole concentration at 260 K was about 4×10¹⁹ cm⁻³. Nevertheless even at that doping level, FIG. 4 shows the beginning of an improvement even at about 300 K. In addition, FIG. 4 further illustrates that the improved Seebeck coefficient of tin doping can be observed for carrier concentrations between about 2×10¹⁹ cm⁻³ and about 8×10¹⁹ cm⁻³ at 300 K (C. Jaworski, V. Kulbachinskii and J. Heremans, “Resonant level formed by tin in Bi₂Te₃ and the enhancement of room-temperature thermoelectric power,” Physical Review B 80, 233201 (2009), incorporated herein in its entirety by reference).

FIG. 6 illustrates a summary of the galvanomagnetic and thermomagnetic measurements; a quantitative analysis is given in the next paragraph. There is a sharp peak in electrical resistivity for both x=0.0075 and x=0.015 at 60 K. Below 300 K, when the samples are extrinsic, the Hall carrier density p=[q ·RH]⁻¹ is shown, which increases with x and shows a sharp increase for 20 K<T<120 K. The thermopower (S) shows a large increase over a simple T¹ law between 15 and 50 K. The Nernst coefficient Nis the largest for x=0.0025 and changes over temperature from negative (T≦250 K) to positive (T>350 K), with its zero point crossing the temperature where S peaks. Both S and N show the onset of the effect of thermally excited electrons at T>300 K (A. F. Ioffe, Physics of Semiconductors (Academic, New York, 1960)).

At T≦250 K, the samples are extrinsic and the measurements of four galvanomagnetic and thermomagnetic properties (ρ₁₁, S₁₁, N₂₁, and R_{H21}) at each temperature were used to deduce four band structure parameters: hole density p, mobility (μ), Fermi energy E_{F} and/or integral density of states effective mass m*_{d}, and scattering exponent λ defined above. Similar measurement procedures are described in J. P. Heremans et al., J. Appl. Phys. 98, 063703 (2005); J. P. Heremans et al., Phys. Rev. B 70, 115334 (2004). The results of the four parameter fit are depicted in FIG. 7. The Fermi levels of the two higher doped samples are “pinned” at approximately 15 and 20 meV, and that when extrapolated to 0 K, lim_{T→0}(E_{F})≈15 meV, is consistent with the results of the SdH measurements. The density of states effective mass m*_{d} of the tin doped samples is approximately double that of the integral density of states mass of the UVB (0.35 mₑ). This suggests the presence of an additional energy level distinct from the LVB, as the LVB has a much heavier mass yet (>1.25 mₑ) (H. Köhler, Phys. Status Solidi B 74, 591 (1976)), and the calculated number of carriers if the second frequency is taken as real is 2 to 5 times more than that of the UVB. This confirms that the resonant level in FIG. 3 is real and that the second SdH frequency of 22 to 27 T is a harmonic, which appears in the Fourier transform of the SdH traces as a result of the spin splitting of the Landau levels. Electrical mobility drops with increasing hole concentration and follows typical temperature dependence which is a mixture of ionized impurity scattering and optical phonon scattering. The scattering exponent λ for the three samples is approximately 0.7≦λ≦1, also indicating that the scattering mechanism is a mixture of ionized impurity and acoustic phonon scattering. This scattering exponent value is much less than the scattering exponent estimated (S. J. Thiagarajan et al., Phys. Status Solidi (RRL) 1, 256 (2007)) for scattering of charge carriers on the sharp excess DOS due to the tin level and a posteriori justifies the assumptions made in calculating the Pisarenko relation.

Using an average dielectric constant of 73 (W. Richter et al., Phys. Status Solidi 84, 619 (1977)), and the masses of H. Köhler, Phys. Status Solidi B 74, 591 (1976), the Bohr radii of the UVB and LVB holes are 48 and 10 nm, respectively. The average distance between tin atoms in our 3 samples being 4, 2.8, and 2.2 nm, respectively, we conclude that the Bohr radii overlap several tin atoms.

In certain embodiments, tin forms a resonant level in Bi₂Te₃ that sufficiently distorts the density of states of the upper valence band to result in a strong increase in thermoelectric power. The thermoelectric power factors P=S²σ of the single crystals are as follows. The x=0.0025% sample has P>45 μW/cm K² from 170 to 300 K, the x=0.015 sample has P>33 μW/cm K² for 240 K<T<360 K. The room temperature in-plane power factor on these samples is considerably increased over that obtained on single-crystal samples of Scherer and Scherer (S. Scherer and H. Scherer, in CRC handbook on Thermoelectricity, edited by D. M. Rowe (CRC Press, Boca Raton, Fla., 1995), Chap. 19, p. 211.) (range from 17 to 27 μW/cm K² which were doped p-type with excess bismuth to the same carrier concentrations. This is mainly due to the increase in Seebeck coefficient while the mobility is not decreased much by the increase in effective mass at the Fermi energy. There is a report in the literature that describes very high-quality single crystals of bismuth-rich Bi₂Te₃ without tin (C. H. Champness and A. L. Kipling, Can. J. Phys. 44, 769 (1966)) with room-temperature mobilities (800 cm²/s) more than four times Scherer's bismuth-rich Bi₂Te₃ which also did not include tin.

Various embodiments have been described above. Although this invention has been described with reference to these specific embodiments, the descriptions are intended to be illustrative of the invention and are not intended to be limiting. Various modifications and applications may occur to those skilled in the art without departing from the true spirit and scope of the invention as defined in the appended claims.

What is claimed is:

1. A thermoelectric material comprising at least one compound having a general composition of (Bi_{1-x-z}SbₓA_{z})ᵤ(Te_{1-y}Se_{y})_{w}, wherein 0≦x≦1, 0≦y≦1, 0<z≦0.10, 1.8≦u ≦2.2, 2.8≦w≦3.2, and the component A comprises at least one Group IV element.

2. The thermoelectric material of claim 1, wherein the A component is selected from the group consisting of tin, lead, and germanium.

3. The thermoelectric material of claim 1, wherein the A component comprises tin.

4. The thermoelectric material of claim 3, wherein the at least one compound comprises a dopant concentration such that the hole concentration is greater than about 2×10¹⁹ cm⁻³ at 300 K.

5. The thermoelectric material of claim 3, wherein the at least one compound comprises a dopant concentration such that the hole concentration is between about 2×10¹⁹ cm⁻³ and about 10×10¹⁹ cm⁻³ between about 260 K and about 300 K.

6. The thermoelectric material of claim 3, wherein the at least one compound comprises a dopant concentration such that the hole concentration is between about 3×10¹⁹ cm⁻³ and about 7×10¹⁹ cm⁻³ between about 260 K and about 300 K.

7. The thermoelectric material of claim 3, wherein 0<z≦0.01.

8. The thermoelectric material of claim 3, wherein 0.005≦z≦0.01.

9. The thermoelectric material of claim 3, wherein 0.005≦z≦0.05.

10. The thermoelectric material of claim 3, wherein the at least one compound comprises at least one tin-induced resonant level.

11. The thermoelectric material of claim 3, wherein the at least one compound comprises at least one tin-induced resonant level and at least one second valence band.

12. The thermoelectric material of claim 3, wherein the at least one compound comprises at least one additional alloying element.

13. A thermoelectric material comprising at least one compound comprising a solid solution of bismuth, tellurium, and tin, wherein the at least one compound further comprises at least one tin-induced resonant level, at least one second valence band, and a dopant concentration such that the hole concentration is between about 2×10¹⁹ cm⁻³ and about 8×10¹⁹ cm⁻³ between about 260 K and about 300 K.

14. A method of using a thermoelectric device comprising:
providing a thermoelectric device comprising a thermoelectric material that comprises at least one compound having a general composition of (Bi_{1-x-z}SbₓA_{z})ᵤ(Te_{1-y}Se_{y})_{w}, wherein 0≦x≦1, 0≦y≦1, 0<z≦0.10, 1.8≦u≦2.2, 2.8≦w≦3.2, and the component A comprises at least one Group IV element; and
exposing at least a portion of the thermoelectric material to a temperature greater than about 173 K during operation of the thermoelectric device.

15. The method of claim 14, wherein 0.005≦z≦0.05.

16. The thermoelectric material of claim 14, wherein the at least one compound comprises at least one tin-induced resonant level.

17. The thermoelectric material of claim 14, wherein the at least one compound comprises at least one tin-induced resonant level and at least one second valence band.

18. The method of claim 14, wherein at least one portion of the thermoelectric material is exposed to a temperature in a range between about 173 K and about 500 K during operation of the thermoelectric device.

19. The method of claim 14, wherein at least one portion of the thermoelectric material is exposed to room temperature during operation of the thermoelectric device.

20. The method of claim 14, wherein at least one portion of the thermoelectric material is exposed to a temperature greater than about 350 K during operation of the thermoelectric device.

21. The method of claim 14, wherein at least one portion of the thermoelectric material is exposed to a temperature between about 260 K and about 300 K during operation of the thermoelectric device and the at least one compound comprises a dopant concentration such that the hole concentration is greater than about 2×10¹⁹ cm⁻³ between about 260 K and about 300 K.

22. The method of claim 14, wherein at least one portion of the thermoelectric material is exposed to a temperature between about 260 K and about 300 K during operation of the thermoelectric device and the at least one compound comprises a dopant concentration such that the hole concentration is between about 2×10¹⁹ cm⁻³ and about 7×10¹⁹ cm⁻³ between about 260 K and about 300 K.
